(19) United States
(12) Patent Application Publication
(10) Pub. No.: US 2006/0202769 A1
(43) Pub. Date: Sep. 14, 2006

(54) Piezoelectric thin film device and method of producing the same

(76) Inventors: Keigo Nagao, Yamaguchi (JP); Kosuke Nishimura, Yamaguchi (JP); Tetsuo Yamada, Yamaguchi (JP); Osamu Otani, Gunma (JP); Sakae Matsuzaki, Gunma (JP)

Correspondence Address: Ronald R Santucci;Frommer Lawrence & Haug, 745 Fifth Avenue, New York, NY, 10151, US

(21) Appl. No.: 10/551,680

(22) PCT Filed: Mar. 30, 2004
(86) PCT No.: PCT/JP04/04507

§ 371 Date: Sep. 29, 2005

(30) Foreign Application Priority Data
Mar. 31, 2003 (JP) 2003-094372

(51) Int. Cl. H03B 5/34

(52) U.S. Cl. 331/73

(57) ABSTRACT

A piezoelectric thin film device (10) comprising a substrate (12) having a vibration space (20), and a piezoelectric lamination structure (14) formed on the upper surface of the substrate, the piezoelectric lamination structure comprising a piezoelectric film (16) and a lower electrode (15) and upper electrode (17) which are formed on opposite surfaces thereof, respectively, the vibration space (20) being so formed as to allow the vibration of a vibrating section (23) constituted by including at least part of the piezoelectric lamination structure (14) and part of an insulating layer (13). The vibrating space (20) is composed of a first via hole (21) formed from the lower surface of the substrate (12) toward the upper surface thereof so as to form an intermediate surface (25) in the substrate, and a second via hole (22) formed from the intermediate surface (23) toward the upper surface of the substrate so as to be positioned inside the first via hole (21) as seen vertically.

### TECHNICAL FIELD

The present invention relates to a piezoelectric thin film device having a single piezoelectric thin film resonator or a combination of plural piezoelectric thin film resonators using a piezoelectric film, and to a producing or manufacturing method thereof. More particularly, the present invention relates to a piezoelectric thin film device that can be used as a filter for communication devices, and to a producing or manufacturing method thereof.

### BACKGROUND ART

Devices using a piezoelectric effect have been used in various fields. In a progress of miniaturization and power saving of mobile devices, application of SAW (Surface Acoustic Wave) devices as RF and IF filters has prevailed more widely. Although SAW filers have responded to strict requirements for high-specs from users, improvements in characteristics of SAW filters have already approached their limits as the frequencies have shifted to higher frequencies. There hence has been a demand for a new technical innovation in view of both of formation of fine intetdigitated electrode and achievement of stable power handling.

On the other side, in a FBAR (Thin Film Bulk Acoustic Resonator) using thickness vibration of piezoelectric thin films, and SBAR (Stacked Thin Film Bulk Acoustic Resonators) and filters, a thin film mainly made of piezoelectric material and electrodes for driving this thin film are formed on a thin support film suspended on a substrate. These resonators can generate basic resonance at a GHz band. If a filter is constituted by a FBAR or SBAR, the device size can be remarkably reduced, and low loss and wide-band operation are available. Besides, the filter can be integrated with a semiconductor integrated circuit. Therefore, it is expected that FBAR or SBAR will be used in future ultraminiature mobile devices.

A resonator which thus uses a bulk acoustic wave, and a piezoelectric thin film resonator such as a FBAR or SBAR which is used in a filter or the like are manufactured as follows.

A base film consisting of a dielectric thin film, a conductive thin film or a stacked film thereof is formed on the surface of a single-crystal semiconductor substrate of silicon or the like, or a substrate made by depositing a film of poly-crystal diamond or constant modulus metal such as elinvar on the surface of a silicon wafer, by any of various thin film forming methods. A piezoelectric thin film is formed on this base film, and further, an upper structure is formed if required. After forming each film or all films, a physical or chemical treatment is performed on each film, thereby to achieve lithography processing or patterning. Next, the substrate is processed by anisotropic etching based on wet process. A part of the substrate positioning below a vibration part comprising the piezoelectric thin film sandwiched with metal electrodes is removed, to create a suspended structure including the vibration part. Finally, each one device unit is separated to obtain a piezoelectric thin film resonator.

For example, in a known conventional piezoelectric thin film resonator, a base film, a lower electrode, a piezoelectric thin film, and an upper electrode are formed on the upper surface of a substrate. Thereafter, a part of the substrate below a part to form a vibration part is etched away from the lower surface side of the substrate, to form a via hole. The resonator is thus manufactured (for example, see JP-58-153412(A) and JP-60-142607(A)). If the substrate is made of silicon, a heated aqueous KOH solution is used to etch and remove a part of the silicon substrate from the lower surface (back face) of the substrate, to form a via hole. In this manner, it is possible to prepare a resonator having such a form as follows. That is, edge parts of a structure in which the piezoelectric film is sandwiched between plural metal electrodes are supported by parts of the silicon substrate around the via hole, in the upper surface side of the silicon substrate.

However, if wet etching using aqueous solution of alkaline such as KOH is carried out, etching proceeds in parallel to the (111) plane. Therefore, etching progresses at an inclination angle of 54.7 degrees to the surface of the (100) silicon substrate. Hence, it is necessary to maintain a remarkably long distance between adjacent resonators. For example, a device having a plan size of about 150 μm×150 μm, which is formed on a silicon wafer having thickness of 550 μm, requires a back-face-side etching opening part of about 930 μm×930 μm, and the distance between the centers of adjacent resonators is 930 μm or more. This causes a problem in that not only integration of FBAR is hindered but also metal electrodes connecting adjacent piezoelectric thin film resonators are so long that the electric resistance of the metal electrodes is very large. Therefore, insertion loss of the piezoelectric thin film device manufactured by combining plural piezoelectric thin film resonators is remarkably great. In addition, if such a large via hole as having an opening part of 930 μm is formed in a substrate, the substrate is not only easily damaged, and further, the quantity (or the number of pieces) of resultant products is limited, i.e., the yield of piezoelectric thin film devices per substrate is limited. Consequently, only 1/20 of the surface area of each substrate can be used as a device area. Alternatively, it is considered that such a large via hole as bridging plural resonators may be formed. In this case, the via hole is much more larger and the strength of the device deteriorates so that the substrate is more easily damaged.

A second conventional method of manufacturing a piezoelectric thin film resonator such as a FBAR or SBAR utilized in a piezoelectric thin film device is to form an air-bridged FBAR device (for example, see JP-2-13109(A)). Usually, a sacrificial layer is provided at first. Next, a piezoelectric thin film resonator is manufactured on this sacrificial layer. At or near the end of process, the sacrificial layer is removed to form a vibration part. Since all processing are carried out on the upper surface side of a substrate, this method requires neither pattern alignment on both surface sides of the substrate nor an opening part having a large area on the lower surface side of the substrate. There is also disclosed the structure of an air-bridged FBAR/SBAR device using phosphorus-doped silica glass (PSG) for the sacrificial layer and a manufacturing method thereof (for example, see JP-2000-69594(A)).

However, this method requires a long complicated process comprising a series of processing steps of: forming a cavity in the upper surface of a substrate by etching; depositing a sacrificial layer on the upper surface side of the substrate by a thermal CVD (Chemical Vapor Deposition) method; planarizing and smoothening the upper surface of the substrate by CMP (Chemical Mechanical Polishing); and depositing a lower electrode, piezoelectric material, and an upper electrode and forming patterns of them by lithograpy on the sacrificial layer. The long complicated process includes: opening a via (hole) penetrating to the cavity; protecting a piezoelectric laminated structure formed on the upper surface side of the substrate, with a resist or the like; and permeating an etching solution through the via, to remove the sacrificial layer from the cavity. Hence, a greatly increased number of masks are used for forming the patterns. Since the manufacturing process is thus long and complicated, the process itself causes a high-cost device, and the yield of products lowers, thereby to raise the costs for devices much more. It is difficult to expand use of such an expensive device as described above, as a general component of a mobile communication device. In addition, the etching solution used to remove the sacrificial layer made of phosphorus-doped silica glass (PSG) or the like erodes each of the lower electrode, piezoelectric material, and upper electrode. Therefore, the material used for the upper structure is not only limited remarkably but also results in a serious problem that it is difficult to manufacture a FBAR or SBAR structure with desired dimensional precision.

A method of manufacturing a piezoelectric thin film device, according to a scheme of forming a vibration space by forming a via hole having a side wall vertical to the surfaces of the substrate by using Deep RIE (reactive ion etching) method from the lower surface side of the substrate, has been proposed (for example, see WO-2004/001964) in order to solve various problems of the foregoing scheme of forming a via hole as a vibration space by anisotropic etching from the lower surface side of a substrate and the other foregoing scheme of forming an air-bridge only on the upper surface side of a substrate. According to the proposed scheme, the side wall of the via hole is vertical. Therefore, adjacent thin film resonators can be so close to each other as in the air-bridge scheme, while complicated processing steps as required by the air-bridge scheme are not necessary. However, in the process of etching a substrate in accordance with a deep RIE method, the etching speed varies depending on positions on the surface of the substrate, if a substrate having such thickness of, for example, 200 to 600 μm that can be handled in the manufacturing process is used. Therefore, the shapes of vibration spaces to be formed or particularly the shapes of substrate opening parts facing a piezoelectric laminated structure differ depending on the positions at which piezoelectric thin film resonators are formed. As a result, it is difficult to manufacture piezoelectric thin film resonators having a required resonant frequency. If plural piezoelectric thin film resonators are manufactured on one substrate, there are variants in resonant frequency among the plural piezoelectric thin film resonators.

The FBAR and SBAR each achieve resonance by propagation of an acoustic waves in the thickness direction in a thin film. Therefore, characteristics thereof are greatly affected not only by uniformity in film thickness of the piezoelectric laminated structure constituted by an insulating layer, lower electrode, piezoelectric thin film, and upper electrode on a substrate but also by precision of the shape of a vibration space. Consequently, it is remarkably difficult to attain plural piezoelectric thin film devices having uniform characteristics in one substrate.

From the grounds as described above, a piezoelectric thin film device which exhibits sufficient performance in a GHz band has not yet been achieved. There hence has been a strong demand for establishment of a method of manufacturing a piezoelectric thin film device, which has simple steps and does not cause characteristic variations depending on positions in a substrate, and for realization of a piezoelectric thin film device manufactured by the method and having stable characteristics.

### DISCLOSURE OF THE INVENTION

The present invention has been made in view of the above problems and has an object of providing a method of manufacturing a piezoelectric thin film device, which is capable of forming a vibration space facing a piezoelectric laminated structure by a simple process with excellent dimensional precision independent from the position in the surface of a substrate, and a piezoelectric thin film device manufactured in this method.

To achieve the object described above, the present inventors have found the following most preferable solution in view of both the stabilization of characteristics of piezoelectric thin film devices and the cost reduction thereof, as a result of dedicated studies and discussions about the method of forming a vibration space. In the most preferable solution, a vibration space is formed by forming a first via hole having a depth smaller than the thickness of the substrate and by forming a second via hole, with the bottom surface of the first via hole used as a reference level.

That is, according to the present invention to achieve the above object, there is provided a piezoelectric thin film device comprising a substrate having a vibration space, and a piezoelectric laminated structure formed on an upper surface side of the substrate, the piezoelectric laminated structure including a piezoelectric film and electrodes formed respectively on both surfaces of the piezoelectric film, and the vibration space being formed so as to allow a vibration part to vibrate, the vibration part including at least a part of the piezoelectric laminated structure, wherein the vibration space is constituted by a first via hole formed from a lower surface of the substrate toward an upper surface thereof with an intermediate surface formed at an intermediate position in the substrate, and a second via hole formed from the intermediate surface toward the upper surface of the substrate, the second via hole being positioned inside the first via hole when viewed in a vertical direction.

According to an aspect of the present invention, plural vibration parts each being the vibration part are formed on the upper surface side of the substrate, the first via hole is formed so as to share a part of each of vibration spaces respectively for the plural vibration parts, and plural second via holes each being the second via hole are formed from the intermediate surface, so as to correspond respectively to the plural vibration parts.

According to another aspect of the present invention, the second via hole is positioned, by at least 2 μm, inside the first via hole when viewed in a vertical direction. According to still another aspect of the present invention, the second via holes has a depth of 10 μm to 150 μm.

Further, according to the present invention to achieve the object described above, there is provided a method of manufacturing a piezoelectric thin film device as described above, wherein, when the vibration space in the substrate is formed, a first via hole is formed from a lower surface of a substrate material toward an upper surface thereof, so as to form a bottom surface of the first via hole at an intermediate position in the substrate, a second via hole is thereafter formed from the bottom surface toward the upper surface of the substrate material, to be positioned inside the first via hole when viewed in a vertical direction, and the intermediate surface is formed by such a part of the bottom surface that remains in the substrate material.

According to an aspect of the present invention, the piezoelectric thin film device has plural vibration parts each being the vibration part, on the upper surface side of the substrate, the first via hole is formed to be shared by the plural vibration parts, plural second via holes each being the second via hole are formed from the bottom surface, so as to correspond respectively to the plural vibration parts. According to another aspect of the present invention, a SOI wafer is used as the substrate material, and the bottom surface of the first via hole is constituted by a part of an insulating layer thereof. According to still another aspect of the present invention, the second via hole is formed by a deep reactive ion etching method.

According to the present invention as described above, a vibration space facing a vibration part can be formed by a simple process with excellent dimensional precision independent from the position in the surface of a substrate. It is therefore possible to provide piezoelectric thin film devices which do not involve characteristic variants depending on positions in the surface of a substrate.

### BRIEF DESCRIPTION OF THE DRAWINGS

FIG. 1 is a schematic plan view showing an embodiment of a piezoelectric thin film device (piezoelectric thin film resonator) according to the present invention;

FIG. 2 is an X-X cross-sectional view of FIG. 1;

FIG. 3 is a schematic plan view showing an embodiment of a piezoelectric thin film device (piezoelectric thin film filter) according to the present invention;

FIG. 4 is an X-X cross-sectional view of FIG. 3;

FIG. 5 is a schematic plan view showing an embodiment of a piezoelectric thin film device (piezoelectric thin film filter) according to the present invention;

FIG. 6 is an X-X cross-sectional view of FIG. 5;

FIG. 7 is a schematic cross-sectional view showing an embodiment of a piezoelectric thin film device of the present invention, built in a microwave package;

FIG. 8 is a schematic plan view showing a piezoelectric thin film device (piezoelectric thin film resonator) used in a comparative example;

FIG. 9 is an X-X cross-sectional view of FIG. 8;

FIG. 10 is a schematic plan view showing a piezoelectric thin film device (piezoelectric thin film filter) used in a comparative example;

FIG. 11 is an X-X cross-sectional view of FIG. 10;

FIG. 12 is a schematic plan view showing a piezoelectric thin film device (piezoelectric thin film resonator) used in a comparative example;

FIG. 13 is an X-X cross-sectional view of FIG. 12; and

FIGS. 14A and 14B are schematic cross-sectional views for explaining an embodiment of a method of manufacturing the piezoelectric thin film device shown in FIG. 1.

### BEST MODE FOR CARRYING OUT THE INVENTION

An embodiment of the present invention will now be described in details hereinafter.

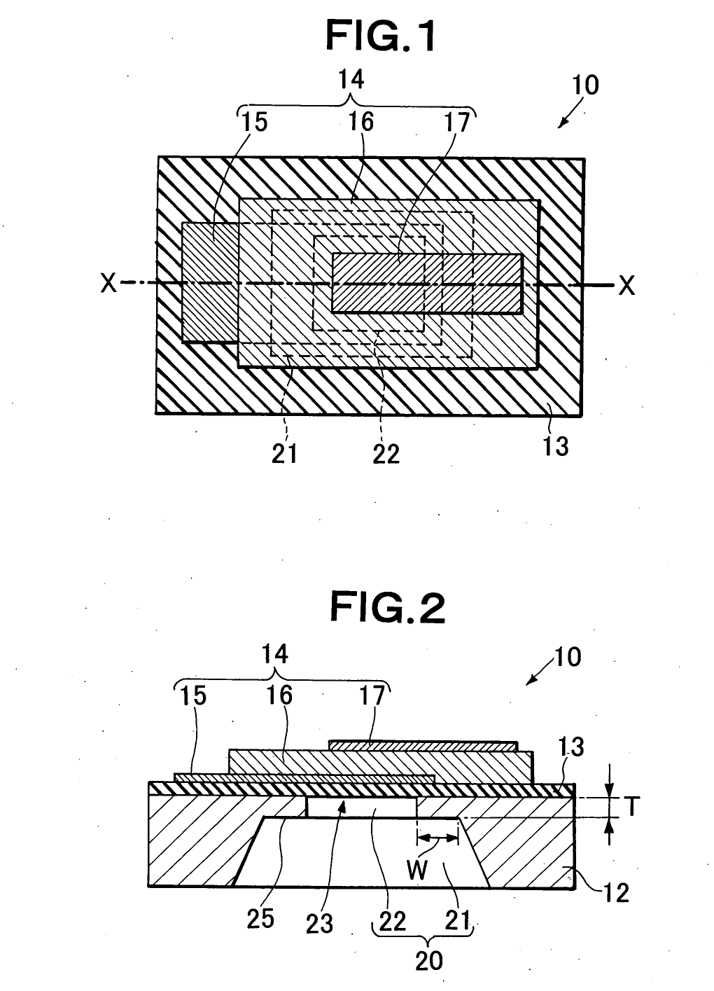

FIG. 1 is a schematic plan view showing an embodiment of the piezoelectric thin film device (piezoelectric thin film resonator 10) according to the present invention. FIG. 2 is an X-X cross-sectional view thereof. In these figures, the piezoelectric thin film resonator 10 has a substrate 12, an insulating layer 13 formed on the upper surface of the substrate 12, and a piezoelectric lamination structure or piezoelectric laminated structure 14 formed on the insulating layer 13. The piezoelectric laminated structure 14 is constituted by a lower electrode 15 formed on the insulating layer 13, a piezoelectric film 16 formed on the insulating layer 13 so as to cover a part of the lower electrode 15, and an upper electrode 17 formed on the piezoelectric film 16.

A first via hole 21 constituting a vibration space 20 is formed in the substrate 12, from the lower surface thereof toward the upper surface thereof. Further, a second via hole 22 also constituting the vibration space 20 is formed, toward the upper surface of the substrate from an intermediate surface 25 facing downward, which corresponds to the bottom surface of the first via hole 21 located at an intermediate position in the substrate 12. As is apparent from FIG. 1, the second via hole 22 is positioned inside the first via hole 21, when the via holes are observed in the vertical direction. Thus, the vibration space 20 is constituted by the first via hole 21 and the second via hole 22.

A part of the insulating layer 13 is exposed to the vibration space 20. The exposed part of the insulating layer 13, and a part of the piezoelectric laminated structure 14 which corresponds to the exposed part of the insulating layer 13 constitute a vibrating section or vibration part (vibration diaphragm) 23. Thus, the vibration space 20 is formed to allow the vibration part 23 to vibrate, the vibration part 23 being formed of parts of the piezoelectric laminated structure 14 and insulating layer 13.

In the present invention, the piezoelectric laminated structure 14 is formed in the upper surface side of the substrate 12. As shown in FIG. 2, another layer (the insulating layer 13 in case of FIG. 2) may be formed on the substrate 12, and the piezoelectric laminated structure 14 may be formed through the layer. Alternatively, the piezoelectric laminated structure 14 may be formed directly on the upper surface of the substrate 12, like in the case of processing the surface layer of the substrate 12 to form another layer (e.g., an insulating layer) in the substrate and forming the piezoelectric laminated structure 14 thereon. Even in case where another layer is interposed between the substrate 12 and the piezoelectric laminated structure 14, the number of layer to be interposed is not limited to one but plural layers may be interposed. The layers to be interposed are not limited to insulating layers.

As the substrate 12, it is possible to use a substrate made of single crystal such as Si (100) single crystal, or a substrate made of base material made of Si single crystal with poly-crystal film formed on the surface of the based material, wherein the poly-crystal film is made of silicon, diamond, or the like. As the substrate 12, it is possible to use still another substrate made of semiconductor or further insulating material.

As the insulating layer 13, it is possible to use, for example, a dielectric film containing silicon oxide (SiO₂) as a major component, another dielectric film containing silicon nitride (SiNₓ) as a major component, or a laminated film consisting of a dielectric film containing silicon oxide as a major component and a dielectric film containing silicon nitride as a major component. With respect to the material of the insulating layer 13, the term of the major component means a constituent contained at a content of 50 equivalent % or more in a dielectric film. The dielectric film may consist of a single layer or of plural layers obtained by adding a layer to tighten contact, etc. Thickness of the insulating layer 13 is, for example, less than 2.0 μm. A method of forming the insulating layer 13 is, for example, a thermal oxidation method of the surface of the substrate 12 or a CVD (Chemical Vapor Deposition) method. In the present invention, it is possible to adopt a piezoelectric thin film resonator having a structure in which the insulating layer 13 is all removed by etching from an area corresponding to the vibration part 23, thereby to expose the lower electrode 15 to the vibration space 20. Since all the insulating layer 13 is thus removed from the area corresponding to the vibration part 23, an acoustic quality factor (Q-value) advantageously improves although temperature coefficients of the resonant frequency deteriorate slightly.

The lower electrode 15 is constituted by a metal layer formed by a sputtering method or vapor deposition method, or by a laminate of such a metal layer and a contact metal layer formed between the metal layer and the insulating layer 13 in accordance with necessity. Thickness of the lower electrode 15 is, for example, 50 nm to 500 nm. Although the material thereof is not particularly limited, material preferably used is gold (Au), platinum (Pt), titanium (Ti), aluminum (Al), molybdenum (Mo), tungsten (W), or the like. As a method of patterning into a predetermined shape, it is possible to use appropriately a photolithography technique such as dry or wet etching or a lift-off method.

Used as the piezoelectric film 16 is a film made of aluminum nitride (AlN), zinc oxide (ZnO), cadmium sulfide (CdS), lead titanate (PbTiO₃, abbreviated as PT), lead zirconate titanate (Pb (Zr, Ti)O₃, abbreviated as PZT), or the like. In particular, AlN allows an acoustic wave to propagate at a high speed and is hence preferable as a piezoelectric film for a piezoelectric thin film resonator or piezoelectric thin film filter which operates at a high frequency band. The thickness thereof is, for example, 0.5 μm to 3.0 μm. As a method of patterning into a predetermined shape, it is possible to use appropriately a photolithography technique such as dry or wet etching.

As the upper electrode 17, a metal layer formed by a sputtering method or vapor deposition method is used, like the lower electrode 15. Material preferably used is gold (Au), platinum (Pt), titanium (Ti), aluminum (Al), molybdenum (Mo), tungsten (W), or the like. The thickness of the upper electrode 17 is, for example, 50 nm to 500 nm. As a method of patterning into a predetermined shape, it is possible to use appropriately a photolithography technique such as dry or wet etching or a lift-off method, like in the case of the lower electrode 15.

A next description will be made of a method of producing or manufacturing a piezoelectric thin film device according to the embodiment shown in FIGS. 1 and 2, and particularly a method of forming the vibration space 20 in the substrate 12 by referring to FIGS. 14A and 14B.

At first, as shown in FIG. 14A, an insulating layer 13 and a piezoelectric laminated structure 14 as described above are formed on the upper surface of a substrate material 12′ which is the material to form the substrate 12.

Next, a protect film for the insulating layer 13 and piezoelectric structure 14 is formed. Then, from the lower surface side of the substrate material 12′, an anisotropic etching method using an alkali-based aqueous solution of potassium hydroxide (KOH), TMAH (tetramethylammonium hydroxide), or the like or a dry etching method using a SF₆ gas is used to form a first via hole 21 as shown in FIG. 14B. The first via hole 21 does not yet reach the upper surface of the substrate material 12′ but a bottom surface 25′ facing downward is formed in the substrate material 12′. This bottom surface 25′ is positioned at a distant T from the upper surface of the substrate material 12′.

After forming the first via hole 21, a spray-type photo-resist coating device or the like is used to coat the entire lower surface of the substrate material 12′ including the bottom surface 25′ of the first via hole with photo-resist. Further, the photo-resist is removed by photolithography from a part corresponding to a vibration part to be formed. Using this patterned photo-resist as a mask, the substrate material 12′ is etched from the bottom surface 25′ of the first via hole toward the upper surface of the substrate material until the insulating layer 13 is exposed, by a dry-etching method using SF₆, etc. or a deep RIE method in which a SF₆ gas and a C₄F₈ gas are used alternately, thereby to form a second via hole 22 as shown in FIGS. 1 and 2.

As a result, a part of the bottom surface 25′ of the first via hole remains as an intermediate surface 25, and a piezoelectric thin film device as shown in FIGS. 1 and 2 is formed. Where viewed in the vertical direction, the second via hole 22 is positioned inside by a distance W from the first via hole 21. That is, the width of the intermediate surface 25 is W. W is preferably 2 μm or more, e.g., 5 μm to 50 μm.

To form the second via hole 22, it is necessary to coat photo-resist on the bottom surface 25′ of the first via hole and to form patterns by photolithography. The thickness of photo-resist to be coated varies depending on the depth of the second via hole 22, and is usually 0.5 μm to 4 μm. Immediately near the peripheral part of the bottom surface 25′, the coated photo-resist easily tends to have non-uniform thickness, due to influence from the nearby side wall. This is a factor which causes deterioration in precision of patterns. Also, immediately near the peripheral part of the bottom surface 25′, processing accuracy due to etching easily deteriorates. Consequently, if the width of the intermediate surface 25 is too small, dimensional precision of the second via hole 22 formed tends to deteriorate to lower the yield. Inversely, if the width of the intermediate surface 25 is too great, the yield of completed products per substrate material tends to decrease. Alternatively, in case of manufacturing a piezoelectric thin film device by combining plural piezoelectric thin film resonators, a metal electrode connecting adjacent piezoelectric thin film resonators to each other is elongated if the width of the intermediate surface 25 is too great. This metal electrode has a so large electric resistance that insertion loss of piezoelectric thin film device manufactured increases.

The depth of the second via hole 22, i.e., the dimension defined by subtracting the depth of the first via hole 21 from the thickness of the substrate 12 is T. T is preferably 10 to 150 μm, more preferably 15 to 100 μm, and much more preferably 20 to 80 μm. If the depth T of the second via hole 22 is too great, the processing accuracy of the second via hole 22 easily tends to deteriorate, lowering the yield. Otherwise, if this depth is too small, the strength of the vibration part 23 and periphery thereof deteriorates. Particularly in a manufacturing process such as a dicing processing step, probability of damages tends to increase remarkably.

As described above, the process of forming via holes constituting the vibration space 20 is divided into two stages. As a result, processing unevenness caused by different etching speeds in the surface of the substrate is reduced more and processed shapes have remarkably improved uniformity, as compared with another method in which via holes are formed through the whole thickness of the substrate at once in one processing step by a dry etching method or deep RIE method. In particular, the characteristics of a resonator are influenced by the shape of the opening part of the vibration space 20 from which the vibration part 23 is exposed, i.e., by the shape of the opening part of the second via hole 22 in the upper surface side of the substrate 12. According to the present invention, however, the second via hole 22 need be formed to reach only the depth T which is smaller as compared with the thickness of the substrate 12. Therefore, a required shape of the opening part of the second via hole 22 can be attained with high precision. Thus, it is possible to manufacture piezoelectric thin film resonators having stable characteristics, independently from their positions in the surface of the substrate.

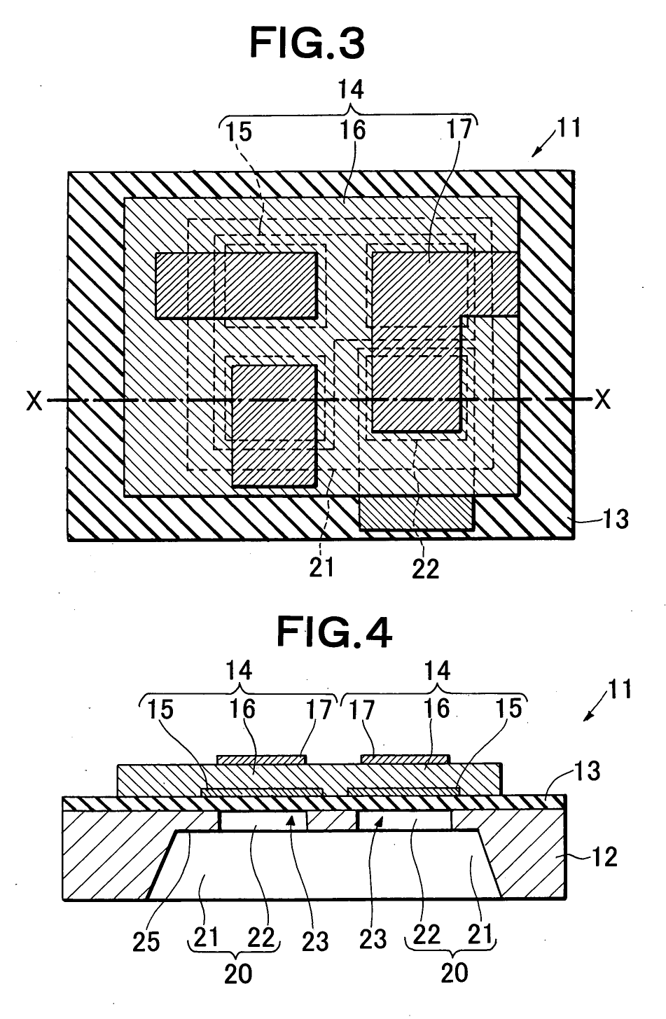

FIG. 3 is a schematic plan view showing an embodiment of a piezoelectric thin film device (piezoelectric thin film filter 11) according to the present invention. FIG. 4 is an X-X cross-sectional view thereof. In these figures, those components that have the same functions as the components shown in FIGS. 1 and 2 are respectively denoted by the same reference symbols.

In the present embodiment, one common first via hole 21 is formed and shared by four vibration parts 23 which are adjacent to each other and are constituted by parts of the piezoelectric laminated structure 14 and parts of the insulating layer 13. Second via holes 22 are formed respectively toward the vibration parts 23 from the intermediate surface 25 corresponding to the bottom surface of the first via hole.

In the present embodiment, the first via hole 21 is formed to be shared by parts of vibration spaces of the plural vibration parts 23. Therefore, even if a substrate 12 having great thickness is used, distances between adjacent vibration parts can be adjusted only by distances between the second via holes. Accordingly, adjacent vibration parts can be so close to each other that the substrate can be effectively utilized and wirings connected to these vibration parts can be shortened. It is hence possible to provide excellent filters with less signal loss.

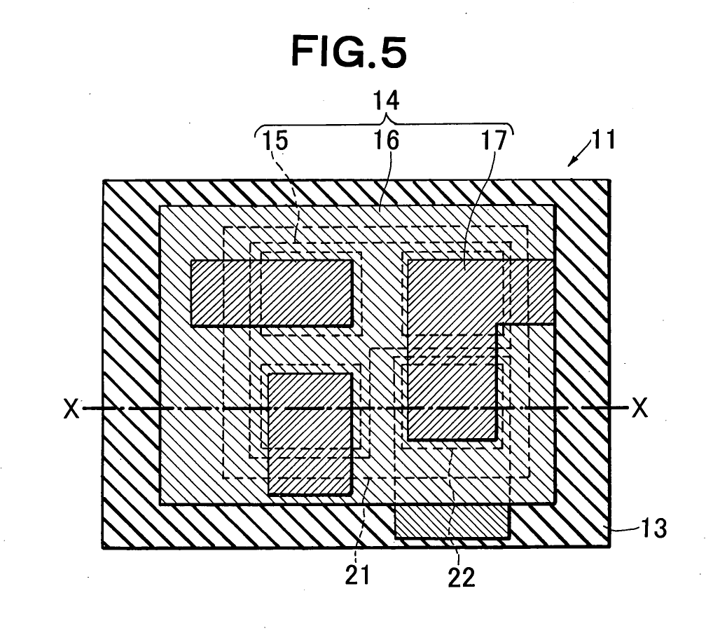

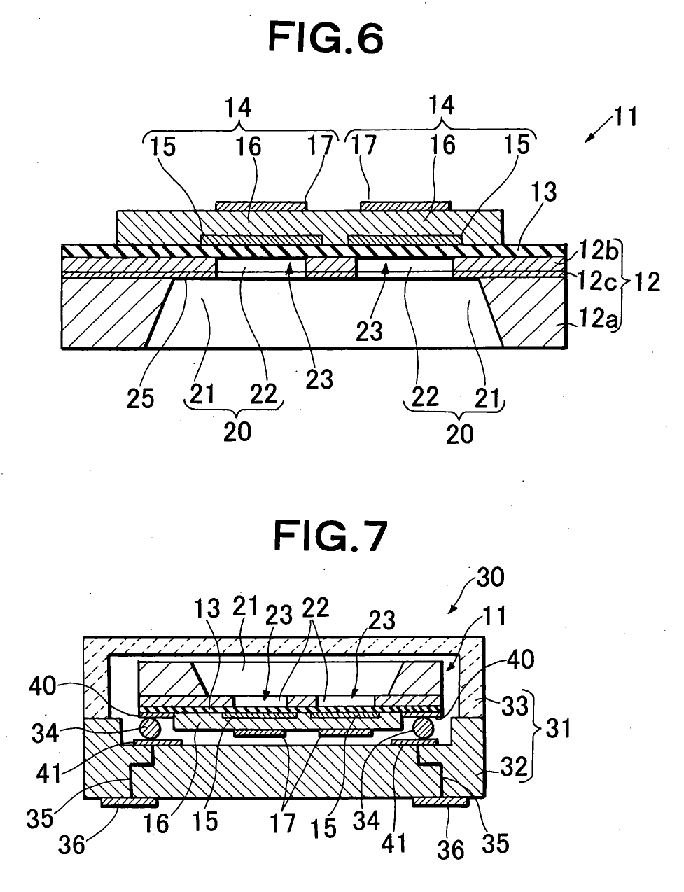

FIG. 5 is a schematic plan view showing still another embodiment of a piezoelectric thin film device (piezoelectric thin film filter 11) according to the present invention. FIG. 6 is an X-X cross-sectional view thereof. In these figures, those components that have the same functions as the components shown in FIGS. 1 to 4 are respectively denoted by the same reference symbols.

In the present embodiment, a SOI (Silicon On Insulator) wafer is used as the substrate 12. The SOI wafer is a wafer obtained by bonding a non-oxidized wafer (base wafer) 12a to the side of the insulating layer 12c of a wafer (bond wafer) 12b on which an insulating layer 12c made of a necessary oxide film is additionally formed. The other side (the active layer side) of the bond wafer 12b is grinded/polished thereby to provide an insulating layer 12c at an arbitrary position in the thickness direction of the substrate 12.

In every one of the wet etching method using an aqueous KOH solution, dry etching method using a SF₆ gas, and the deep RIE method in which a SF₆ gas and a C₄F₈ gas are used alternately, the difference in etching speed (i.e., selected etching ratio) between Si and SiO₂ which is oxide of Si is utilized. This etching speed difference is usually as great as about 100 to 400. That is, the etching speed of SiO₂ is much smaller than that of Si. Hence, if the oxide film (SiO₂) 12c of the SOI wafer is used as an end point when forming the first via hole 21, the position (depth) of the intermediate surface 25 of the first via hole 21 in the substrate can be controlled with much higher precision.

To form the second via holes 22, the insulating layer-12c of the SOI wafer is etched and removed, into a predetermined shape, by photolithography with use of a hydrofluoric-acid buffer solution, so as to form appropriate vibration parts 23. With a remaining insulating layer singly used as a mask or with the remaining insulating layer and remaining photo-resist both used as masks, the deep RIE method is carried out. Therefore, the processing precision improves remarkably so that a piezoelectric thin film filter having uniform characteristics throughout the entire area in the surface of the substrate can be manufactured.

Hereinafter, the present invention will be described in more details, referring to examples and comparative examples.

### EXAMPLE 1

In this example, plural piezoelectric thin film devices (piezoelectric thin film resonators) having the structure as shown in FIGS. 1 and 2 were prepared with use of common substrate in the following manner.

Specifically, a SiO₂ layer which was 0.3 μm thick was formed, by a thermal oxidation method, on each of two surfaces of a 4-inch (100) Si wafer which was 200 μm thick. Thereafter, photo-resist was coated on the upper surface of the Si wafer, to form a resist pattern for lower electrodes, as shown in FIG. 1. On the upper surface of this Si wafer, a Mo layer having thickness of 0.23 μm was formed by a DC magnetron sputtering method under conditions of a gas pressure of 0.5 Pa and a substrate temperature of 150° C. Thereafter, ultrasonic cleaning was carried out in a resist-separation solution, to pattern the Mo layer into a desired shape. Thus, lower electrodes were formed. Next, an AlN piezoelectric film having thickness of 1.40 μm was formed on the upper surface of the wafer by a reactive magnetron sputtering method with use of an Al target having purity of 99.999% under conditions of a total gas pressure of 0.5 Pa, a gas composition Ar/N₂=1/1, and a substrate temperature of 300° C. Next, the AlN piezoelectric film was patterned into a predetermined shape as shown in FIG. 1, by wet etching using hot phosphoric acid. Subsequently, photo-resist was coated and patterned into a predetermined shape with use of a photo-mask for upper electrodes. Thereafter, a Mo layer having thickness of 0.17 μm was formed by a DC magnetron sputtering method. Further, ultrasonic cleaning was carried out in a resist separation solution, to pattern the Mo layer into a desired shape. Thus, upper electrodes were formed.

In the method as described above, an insulating layer made of a thermal oxide film and a piezoelectric laminated structure were formed on the upper surface side of a Si wafer. Photo-resist was coated on the lower surface side of the Si wafer, and patterned with use of a photo-mask for first via holes. Part of the thermal oxide film on the lower surface side was removed with use of a hydrofluoric-acid buffer solution. Subsequently, with this thermal oxide film used as a mask, wet etching was carried out in an aqueous KOH solution, to the depth of 150 μm equivalent to 75% of the substrate thickness. Thus, plural first via holes were formed.

Subsequently, a spray-type photo-resist coating device was used to coat photo-resist on the entire lower surface of the substrate including the bottom surface of the first via holes. Further, a photo-mask having a shape identical to the shape of vibration parts to be formed was used to pattern the photo-resist. With this patterned photo-resist used as a mask, etching was carried out by a deep RIE device until the thermal oxide film formed on the upper surface of the wafer was exposed. Thus, second via holes each having a shape whose side wall stood vertically were formed. Thus, vibration spaces constituted by first and second via holes were created. Intermediate surfaces had a minimum width of 5 μm.

Through the manufacturing process as described above, plural vibration parts were formed and plural piezoelectric thin film resonators were formed over the entire surface of the 4-inch Si substrate. Resonant frequencies of the piezoelectric thin film resonators formed were evaluated with use of a network analyzer. A GSG micro probe was put in contact with I/O terminals of the resonators.

Table 1 shows the size and thickness of the substrate, the depths of the first and second via holes (which may be simply called “via”: same in the following), the damage rate of obtained piezoelectric thin film resonators, the frequency distribution, and the device yield (which is a rate of acceptable products without damages within the range of frequency distribution ±0.1%), in this example.

TABLE 1

| | | Substrate size | | Via depth (μm) | | | | Frequency | |
|---|---|---|---|---|---|---|---|---|---|
| | Device | Diameter | Thickness | First | | Device size | Damage rate | distribution | Device yield |
| | structure | (inch) | (μm) | via | Second via | (mm square) | (%) | (%) | (%) |
| Example 1 | | 4 | 200 | 150 | 50 | 1.0 | 0.4 | ±0.18 | 85 |
| Example 2 | | 4 | 200 | 180 | 20 | 1.0 | 1.0 | ±0.11 | 97 |
| Example 3 | | 4 | 200 | 100 | 100 | 1.0 | 0.2 | ±0.35 | 58 |
| Example 4 | | 6 | 300 | 240 | 60 | 1.0 | 0.4 | ±0.23 | 71 |
| Example 5 | | 6 | 300 | 200 | 100 | 1.0 | 0.2 | ±0.42 | 54 |
| Example 6 | | 6 | 550 | 500 | 50 | 1.0 | 0.6 | ±0.19 | 80 |
| Example 7 | | 6 | 550 | 530 | 20 | 1.0 | 1.2 | ±0.12 | 94 |
| Comp. Ex. 1 | | 4 | 200 | — | — | 1.0 | 5.0 | ±1.00 | 20 |
| Comp. Ex. 2 | | 6 | 300 | — | — | 1.0 | 7.0 | ±3.30 | 5 |
| Comp. Ex. 3 | | 4 | 200 | — | — | 2.4 | 12.0 | ±0.55 | 33 |

### EXAMPLE 2

In this example, piezoelectric thin film devices (piezoelectric thin film resonators) having the structure as shown in FIGS. 1 and 2 were prepared in the following manner.

Specifically, piezoelectric thin film resonators were prepared in the same method as in the example 1 except that the depths of the first and second via holes were respectively set to 180 μm and 20 μm.

Table 1 shows the size and thickness of the substrate, the depths of the first and second via holes, the damage rate of obtained piezoelectric thin film resonators, the frequency distribution, and the device yield, in this example.

### EXAMPLE 3

In this example, piezoelectric thin film devices (piezoelectric thin film resonators) having the structure as shown in FIGS. 1 and 2 were prepared in the following manner.

Specifically, piezoelectric thin film resonators were prepared in the same method as in the example 1 except that the depths of the first and second via holes were respectively set to 100 μm and 100 μm.

Table 1 shows the size and thickness of the substrate, the depths of the first and second via holes, the damage rate of obtained piezoelectric thin film resonators, the frequency distribution, and the device yield, in this example.

### EXAMPLE 4

In this example, piezoelectric thin film devices (piezoelectric thin film filters) having the structure as shown in FIGS. 3 and 4 were prepared in the following manner.

Specifically, piezoelectric thin film filters were prepared in the same method as in the example 1 except that a 6-inch (100) Si wafer having thickness of 300 μm was used and the depths of the first and second via holes were respectively set to 240 μm and 60 μm.

Table 1 shows the size and thickness of the substrate, the depths of the first and second via holes, the damage rate of obtained piezoelectric thin film filters, the frequency distribution, and the device yield, in this example.

### EXAMPLE 5

In this example, piezoelectric thin film devices (piezoelectric thin film filters) having the structure as shown in FIGS. 3 and 4 were prepared in the following manner.

Specifically, piezoelectric thin film filters were prepared in the same method as in the example 4 except that the depths of the first and second via holes were respectively set to 200 μm and 100 μm.

Table 1 shows the size and thickness of the substrate, the depths of the first and second via holes, the damage rate of obtained piezoelectric thin film filters, the frequency distribution, and the device yield, in this example.

### EXAMPLE 6

In this example, plural piezoelectric thin film devices (piezoelectric thin film filters) having the structure as shown in FIGS. 5 and 6 were prepared with use of common substrate in the following manner.

Specifically, a SiO₂ layer which was 0.5 μm thick was formed, by a thermal oxidation method, on each of two surfaces of a 6-inch SOI wafer which was 550 μm thick (active layer thickness: 50 μm, insulating layer thickness: 0.5 μm). Thereafter, photo-resist was coated on the upper surface side (active layer side) of the wafer, to form a resist pattern for lower electrodes, as shown in FIGS. 5 and 6. On the upper surface of the wafer, a Mo Layer having thickness of 0.23 μm was formed by a DC magnetron sputtering method under conditions of a gas pressure of 0.5 Pa and a substrate temperature of 150° C. Thereafter, ultrasonic cleaning was carried out in a resist separation solution, to pattern the Mo layer into a desired shape. Thus, lower electrodes were formed. Next, an AlN piezoelectric film having thickness of 1.40 μm was formed on the upper surface of the wafer by a reactive magnetron sputtering method with use of an Al target having purity of 99.999% under conditions of a total gas pressure of 0.5 Pa, a gas composition Ar/N₂=1/1, and a substrate temperature of 300° C. Next, the AlN piezoelectric film was patterned into a predetermined shape as shown in FIGS. 5 and 6, by wet etching using hot phosphoric acid. Subsequently, photo-resist was coated and patterned into a predetermined shape with use of a photo-mask for upper electrodes. Thereafter, a Mo layer having thickness of 0.17 μm was formed by a DC magnetron sputtering method. Further, ultrasonic cleaning was carried out in a resist separation solution, to pattern the Mo layer into a desired shape. Thus, upper electrodes were formed.

In the method as described above, an insulating layer made of a thermal oxide film and a piezoelectric laminated structure were formed on the upper surface side of a SOI wafer. Photo-resist was coated on the lower surface side of the SOI wafer, and patterned with use of a photo-mask for a first via hole. Part of the thermal oxide film on the lower surface side was removed with use of a hydrofluoric-acid buffer solution. Subsequently, with this thermal oxide film used as a mask, wet etching was carried out in an aqueous KOH solution, to reach an insulating layer of the SOI wafer. Subsequently, a spray-type photo-resist coating device was used to coat photo-resist on the entire lower surface of the substrate including the bottom surface of the first via hole. Further, a photo-mask having a shape identical to the shape of vibration parts to be formed was used to pattern the photo-resist. Subsequently, part of the insulating layer of the SOI wafer was removed with use of a hydrofluoric-acid buffer solution. With remaining photo-resist and remaining part of the insulating layer used as masks, etching was carried out by a deep RIE device until the thermal oxide film formed on the upper surface of the wafer was exposed. Second via holes were thus formed. Thus, vibration spaces constituted by first and second via holes were created.

Through the manufacturing process as described above, plural vibration parts were formed and plural piezoelectric thin film filters were formed over the entire surface of the 6-inch SOI substrate. Center frequencies of the piezoelectric thin film filters formed were evaluated with use of a network analyzer. A GSG micro probe was put in contact with I/O terminals of the resonators.

Table 1 shows the size and thickness of the substrate, the depths of the first and second via holes, the damage rate of obtained piezoelectric thin film filters, the frequency distribution, and the device yield, in this example.

### EXAMPLE 7

In this example, piezoelectric thin film devices (piezoelectric thin film filters) having the structure as shown in FIGS. 5 and 6 were prepared in the following manner.

Specifically, piezoelectric thin film filters were prepared in the same method as in the example 6 except that a SOI wafer having an active layer which is 20 μm thick and an insulating layer which is 0.5 μm thick is used.

Table 1 shows the size and thickness of the substrate, the depths of the first and second via holes, the damage rate of obtained piezoelectric thin film filters, the frequency distribution, and the device yield, in this example.

Further, the substrate in which plural piezoelectric thin film devices were created by the process described above was cut into pieces of devices each having a shape which is a little smaller than a 1 mm square with use of a dicing saw. A desired chip was obtained for every device. For the convenience of handling, the chip was built in a ceramic package as shown in FIG. 7. In a general ceramic package, connection to a chip having plural input/output pads is achieved by wire bonding. In this example, however, a flip-chip bonding technique was utilized to reduce the device size.

FIG. 7 shows a device 30 constituted by mounting a chip of the piezoelectric thin film filter 11 in a microwave package 31 by flip-chip bonding. The package 31 is constituted by a package substrate 32 and a cap 33. A bonding pad 40 connected to a lower or upper electrode of the piezoelectric thin film filter 11 is connected, through a junction member 34 such as an Au bump or a solder bump, to a signal channel 35 provided in the microwave package 31 made of ceramics or the like. The signal channel 35 extends inside the package substrate 32 made of ceramics or the like and communicates with an external terminal 36 provided outside the package. If the chip shape is a 1 mm square, the device size is a 3 mm square according to the connection method based on the wire bonding while downsizing approximately to a 2.3 mm square can be achieved by the flip-chip bonding.

### COMPARATIVE EXAMPLE 1

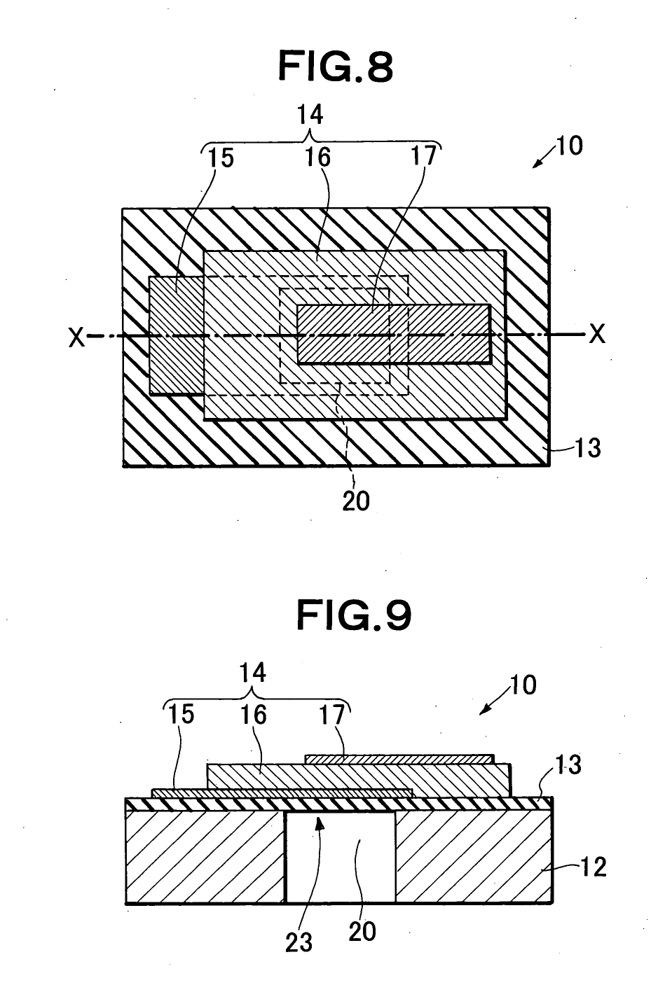

In this comparative example, piezoelectric thin film resonators having the structure as shown in FIGS. 8 and 9 were prepared in the following manner. In these figures, those components that have the same functions as the components shown in FIGS. 1 and 2 are denoted by the same reference symbols.

Specifically, an insulating layer and a piezoelectric laminated structure were prepared on the upper surface side of a substrate by the same method as described in the example 1.

Next, photo-resist was coated on the lower surface side of the Si wafer, and patterned with use of a photo-mask for forming second via holes as shown in the example 1. Part of the thermal oxide film on the lower surface side was removed with use of a hydrofluoric-acid buffer solution. Subsequently, with remaining part of the thermal oxide film and remaining photo-resist used as masks, etching was carried out by a deep RIE device until the thermal oxide film formed on the upper surface of the wafer was exposed. Thus, via holes having side walls standing vertically were formed, and vibration spaces were thereby created.

Through the manufacturing process as described above, plural piezoelectric thin film resonators were formed over the entire surface of a 4-inch Si substrate. Resonant frequencies of the piezoelectric thin film resonators formed were evaluated with use of a network analyzer. A GSG micro probe was put in contact with I/O terminals of the resonators.

Table 1 shows the size and thickness of the substrate, the damage rate of obtained piezoelectric thin film resonators, the frequency distribution, and the device yield, in this comparative example.

### COMPARATIVE EXAMPLE 2

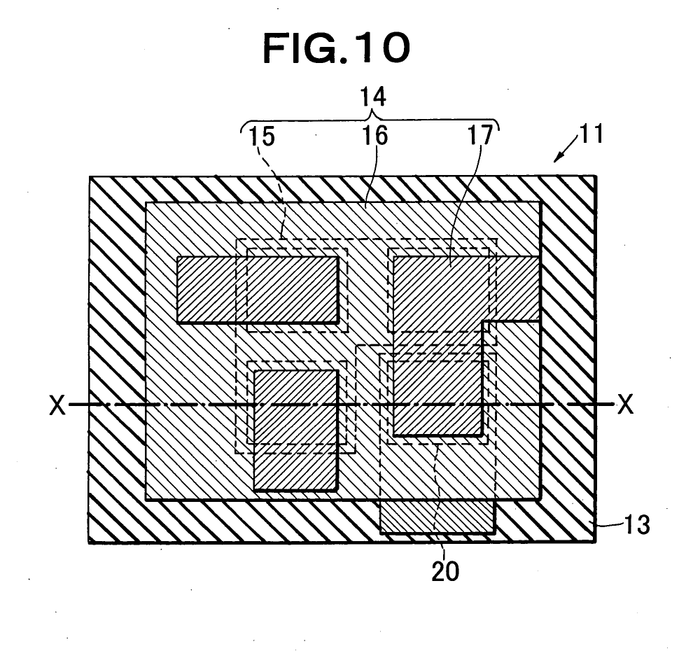

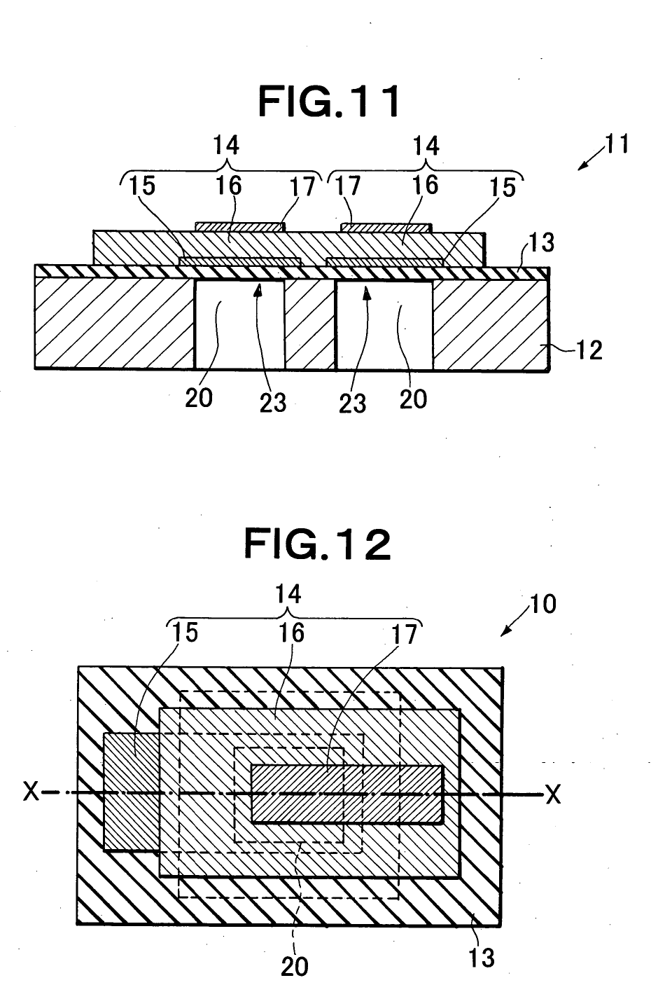

In this comparative example, piezoelectric thin film filters having the structure as shown in FIGS. 10 and 11 were prepared in the following manner. In these figures, those components that have the same functions as the components shown in FIGS. 3 and 4 are denoted by the same reference symbols.

Specifically, an insulating layer and a piezoelectric laminated structure were prepared on the upper surface side of a substrate by the same method as described in the example 4.

Next, photo-resist was coated on the lower surface side of the Si wafer, and was patterned with use of a photo-mask for forming second via holes as shown in the example 4. Part of the thermal oxide film on the lower surface side was removed with use of a hydrofluoric-acid buffer solution. Subsequently, with remaining part of the thermal oxide film and remaining photo-resist used as masks, etching was carried out by a deep RIE device until the thermal oxide film formed on the upper surface of the wafer was exposed. Thus, via holes having side walls standing vertically were formed, and vibration spaces were thereby created.

Through the manufacturing process as described above, plural piezoelectric thin film filters were formed over the entire surface of a 6-inch Si substrate. Center frequencies of the piezoelectric thin film filters formed were evaluated with use of a network analyzer. A GSG micro probe was put in contact with I/O terminals of the resonators.

Table 1 shows the size and thickness of the substrate, the damage rate of obtained piezoelectric thin film filters, the frequency distribution, and the device yield, in this comparative example.

### COMPARATIVE EXAMPLE 3

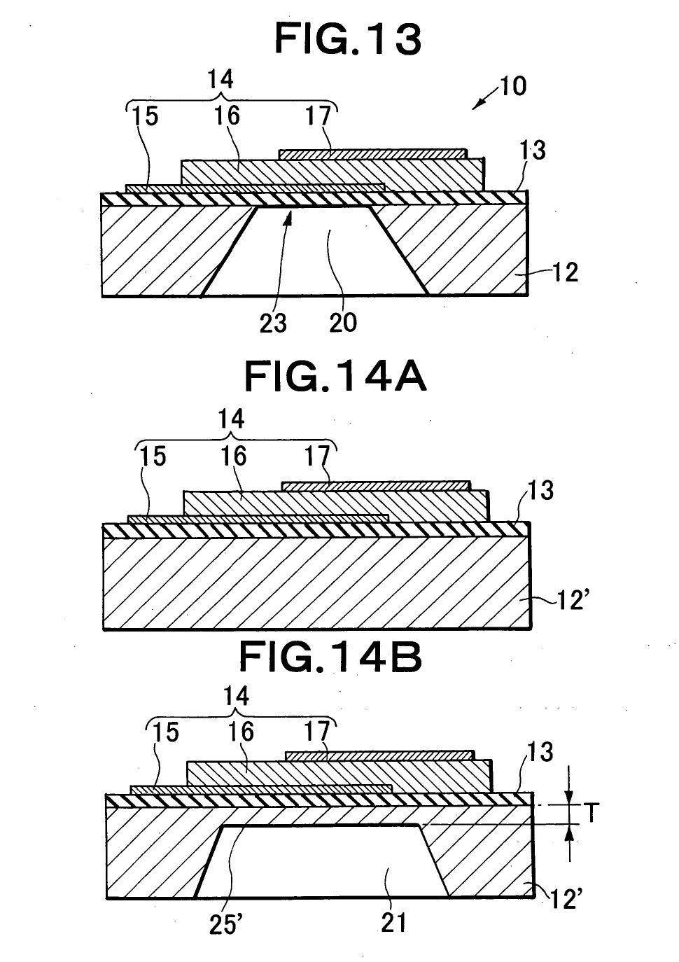

In this comparative example, piezoelectric thin film resonators having the structure as shown in FIGS. 12 and 13 were prepared in the following manner. In these figures, those components that have the same functions as the components shown in FIGS. 1 and 2 are denoted by the same reference symbols.

Specifically, an insulating layer and a piezoelectric laminated structure were prepared on the upper surface side of a substrate by the same method as described in the example 1 except that photo-masks different from those used in the example 1 were used.

Next, photo-resist was coated on the lower surface side of a Si wafer, and patterned with use of a photo-mask for via hole formation for wet etching. Part of the thermal oxide film on the lower surface side was removed with use of a hydrofluoric-acid buffer solution. Subsequently, with this thermal oxide film used as a mask, anisotropic etching was carried out until the thermal oxide film formed on the upper surface of the wafer was exposed. Thus, via holes were formed, and vibration spaces were thereby created.

Through the manufacturing process as described above, plural piezoelectric thin film resonators were formed over the entire surface of a 4-inch Si substrate. Resonant frequencies of the piezoelectric thin film resonators formed were evaluated with use of a network analyzer. A GSG micro probe was put in contact with I/O terminals of the resonators.

Table 1 shows the size and thickness of the substrate, the damage rate of obtained piezoelectric thin film resonators, the frequency distribution, and the device yield, in this comparative example.

Further, a piezoelectric thin film filter was constructed by combining plural pieces of piezoelectric thin film resonators described in this comparative example. However, metal electrodes (wiring parts) connecting adjacent piezoelectric thin film resonators to each other were elongated. Therefore, insertion loss increased remarkably so that performance of the plural resonators working as a piezoelectric thin film filter cannot be checked.

### INDUSTRIAL APPLICABILITY

According to the present invention, the second via hole corresponding to the vibration part is formed from the bottom surface of the first via hole, to form the vibration space in a substrate. Therefore, the process of manufacturing a piezoelectric thin film device is simplified. In addition, it is possible to reduce influence of difference in etching speed which appear when forming plural via holes, especially the second via holes, in the surface of the substrate, and to obtain uniform processed shapes. Accordingly, characteristics of piezoelectric thin film device can be stabilized remarkably, independently from the position in the surface of a substrate.

1. A piezoelectric thin film device comprising a substrate having a vibration space, and a piezoelectric laminated structure formed on an upper surface side of the substrate, the piezoelectric laminated structure including a piezoelectric film and electrodes formed respectively on both surfaces of the piezoelectric film, and the vibration space being formed so as to allow a vibration part to vibrate, the vibration part including at least a part of the piezoelectric laminated structure, wherein the vibration space is constituted by a first via hole formed from a lower surface of the substrate toward an upper surface thereof with an intermediate surface formed at an intermediate position in the substrate, and a second via hole formed from the intermediate surface toward the upper surface of the substrate, the second via hole being positioned inside the first via hole when viewed in a vertical direction.

2. The piezoelectric thin film device as claimed in claim 1, wherein plural vibration parts each being the vibration part are formed on the upper surface side of the substrate, the first via hole is formed so as to share a part of each of vibration spaces respectively for the plural vibration parts, and plural second via holes each being the second via hole are formed from the intermediate surface, so as to correspond respectively to the plural vibration parts.

3. The piezoelectric thin film device as claimed in claim 1, wherein the second via hole is positioned, by at least 2 μm, inside the first via hole when viewed in a vertical direction.

4. The piezoelectric thin film device as claimed in claim 1, wherein the second via holes has a depth of 10 μm to 150 μm.

5. A method of manufacturing a piezoelectric thin film device of claim 1, wherein, when the vibration space in the substrate is formed, a first via hole is formed from a lower surface of a substrate material toward an upper surface thereof, so as to form a bottom surface of the first via hole at an intermediate position in the substrate, a second via hole is thereafter formed from the bottom surface toward the upper surface of the substrate material, to be positioned inside the first via hole when viewed in a vertical direction, and the intermediate surface is formed by such a part of the bottom surface that remains in the substrate material.

6. The method as claimed in claim 5, wherein the piezoelectric thin film device has plural vibration parts each being the vibration part, on the upper surface side of the substrate, the first via hole is formed to be shared by the plural vibration parts, plural second via holes each being the second via hole are formed from the bottom surface, so as to correspond respectively to the plural vibration parts.

7. The method as claimed in claim 5, wherein a SOI wafer is used as the substrate material, and the bottom surface of the first via hole is constituted by a part of an insulating layer thereof.

8. The method as claimed in claim 5, wherein the second via hole is formed by a deep reactive ion etching method.

9. The piezoelectric thin film device as claimed in claim 3, wherein the second via hole is positioned inside by a distance of 5 μm to 50 μm from a peripheral part of a bottom surface of the first via hole.

10. The piezoelectric thin film device as claimed in claim 1, wherein an insulating layer is formed between the upper surface of the substrate and the piezoelectric laminated structure, the vibration part includes a part of the insulating layer, and the insulating layer has a thickness of 0.3 μm to 0.5 μm.

11. The piezoelectric thin film device as claimed in claim 2, wherein a distribution of resonant frequencies of piezoelectric thin film resonators each corresponding to the respective plural vibration parts is within +0.42%.

12. The method as claimed in claim 5, wherein, when forming the second via hole, photo-resist is coated on the bottom surface of the first via hole at a thickness of 0.5 μm to 4 μm, then the photo-resist is patterned by removing a part thereof corresponding to the vibration part, the vibration part being positioned inside by a distance of 2 μm or more from a peripheral part of a bottom surface of the first via hole, then the substrate material is etched with the patterned photo-resist used as a mask.

13. The method as claimed in claim 12, wherein the vibration part is positioned inside by a distance of 5 μm to 50 μm from the peripheral part of the bottom surface of the first via hole.

14. The method as claimed in claim 6, wherein a distribution of resonant frequencies of piezoelectric thin film resonators each corresponding to the respective plural vibration parts is within ±0.42%.

15. A method of manufacturing a piezoelectric thin film device of claim 2, wherein, when the vibration space in the substrate is formed, a first via hole is formed from a lower surface of a substrate material toward an upper surface thereof, so as to form a bottom surface of the first via hole at an intermediate position in the substrate, a second via hole is thereafter formed from the bottom surface toward the upper surface of the substrate material, to be positioned inside the first via hole when viewed in a vertical direction, and the intermediate surface is formed by such a part of the bottom surface that remains in the substrate material.

16. A method of manufacturing a piezoelectric thin film device of claim 3, wherein, when the vibration space in the substrate is formed, a first via hole is formed from a lower surface of a substrate material toward an upper surface thereof, so as to form a bottom surface of the first via hole at an intermediate position in the substrate, a second via hole is thereafter formed from the bottom surface toward the upper surface of the substrate material, to be positioned inside the first via hole when viewed in a vertical direction, and the intermediate surface is formed by such a part of the bottom surface that remains in the substrate material.

17. A method of manufacturing a piezoelectric thin film device of claim 4, wherein, when the vibration space in the substrate is formed, a first via hole is formed from a lower surface of a substrate material toward an upper surface thereof, so as to form a bottom surface of the first via hole at an intermediate position in the substrate, a second via hole is thereafter formed from the bottom surface toward the upper surface of the substrate material, to be positioned inside the first via hole when viewed in a vertical direction, and the intermediate surface is formed by such a part of the bottom surface that remains in the substrate material.
